(19) United States
(12) Patent Application Publication
(10) Pub. No.: US 2025/0058827 A1
(43) Pub. Date: Feb. 20, 2025

(54) DEVICE AND METHOD FOR DETECTING ABNORMALITY OF REAR WHEEL STEERING MOTOR, AND NON-TRANSITORY COMPUTER-READABLE STORAGE MEDIUM STORING PROGRAM FOR PERFORMING THE METHOD

(71) Applicant: HL MANDO CORPORATION, Pyeongtaek-si (KR)

(72) Inventor: Gyuwon KIM, Pyeongtaek-si (KR)

(73) Assignee: HL MANDO CORPORATION, Pyeongtaek-si (KR)

(21) Appl. No.: 18/804,826

(22) Filed: Aug. 14, 2024

(30) Foreign Application Priority Data
Aug. 14, 2023 (KR) 10-2023-0106182
Jul. 8, 2024 (KR) 10-2024-0089573

(51) Int. Cl. B62D 7/15

(52) U.S. Cl. CPC B62D 7/159

(57) ABSTRACT

Disclosed are a device and method for detecting an abnormality of a rear wheel steering motor, and a non-transitory computer-readable storage medium storing a program for performing the method. The device includes a memory configured to store one or more instructions, and a processor configured to execute the one or more instructions. The processor executes the one or more instructions to input, into an artificial neural network model, input data related to the rear wheel steering of the vehicle, obtain, from the artificial neural network model, estimated data related to the rear wheel steering of the vehicle, as output data, obtain, from a sensor, measured data related to the rear wheel steering of the vehicle, compare the estimated data and the measured data, and detect the abnormality of the rear wheel steering motor based on a result of the comparison of the estimated data and the measured data.

### CROSS-REFERENCE TO RELATED APPLICATION

This application claims priority to and benefit from Korean Patent Application No. 10-2023-0106182, filed on Aug. 14, 2023, and Korean Patent Application No. 10-2024-0089573, filed on Jul. 8, 2024, the disclosures of which are incorporated herein by reference in their entireties.

### BACKGROUND

### 1. Technical Field

The present disclosure relates to a device and method for detecting an abnormality of a rear wheel steering motor, and a non-transitory computer-readable storage medium storing a program for performing the method, and more specifically, to a device and method for detecting an abnormality of a rear wheel steering motor that is capable of detecting the abnormality of the rear wheel steering motor that generates a driving force for driving a rack that performs rear wheel steering of a vehicle, and a non-transitory computer-readable storage medium storing a program for performing the method.

### 2. Discussion of Related Art

A rear wheel steering system of a vehicle actively controls a steering angle of rear wheels to match a steering angle of front wheels according to a driving situation of the vehicle. The rear wheel steering system enables a turning radius of a vehicle to be reduced and driving stability and ride comfort to be improved.

A rear wheel steering system includes a rack that adjusts the angle of rear wheels of the vehicle and a rear wheel steering actuator that drives the rack. Generally, a rear wheel steering actuator includes a motor. That is, the rear wheel steering actuator may be a rear wheel steering motor.

An output torque of a rear wheel steering motor may be decreased due to demagnetization, insulation corrosion, etc., caused by its degradation. When the output torque of the rear wheel steering motor is decreased, a driver receives feedback of unpleasant riding feeling that is different from his or her steering intention. The feedback of the unpleasant riding feeling may cause accidents due to steering errors.

Generally, an output torque of a rear wheel steering motor is decreased gradually. Therefore, in order to improve the safety of a rear wheel steering system, it is desirable to prognosticate an abnormality of a motor. However, conventional approaches related to detecting an abnormality of a rear wheel steering motor are limited to post-failure diagnosis.

### SUMMARY OF THE INVENTION

The present disclosure is directed to providing a device and method for detecting an abnormality of a rear wheel steering motor that is capable of detecting degradation in performance of the rear wheel steering motor that generates a driving force for driving a rack that performs rear wheel steering of a vehicle before a failure occurs, and a non-transitory computer-readable storage medium storing a program for performing the method.

The present disclosure is also directed to providing a device and method for detecting an abnormality of a rear wheel steering motor that is capable of efficiently detecting in advance a decrease in an output of the rear wheel steering motor by using an existing sensor disposed on a vehicle in the vehicle without an additional sensor, and a non-transitory computer-readable storage medium storing a program for performing the method.

The objects of the present disclosure are not limited to the above-described objects, and other objects that are not mentioned will be able to be clearly understood by those skilled in the art to which the present disclosure pertains from the following description.

According to an aspect of the present disclosure, there is provided a device for detecting an abnormality of a rear wheel steering motor, which includes a memory configured to store one or more instructions, and a processor configured to execute the one or more instructions. The processor executes the one or more instructions to input, into an artificial neural network model, input data related to the rear wheel steering of the vehicle, obtain, from the artificial neural network model, estimated data related to the rear wheel steering of the vehicle, as output data, obtain, from a sensor, measured data related to the rear wheel steering of the vehicle, compare the estimated data and the measured data, and detect the abnormality of the rear wheel steering motor based on a result of the comparison of the estimated data and the measured data.

According to another aspect of the present disclosure, there is provided a method of detecting an abnormality of a rear wheel steering motor of a vehicle, which includes inputting, by a processor, into an artificial neural network model, input data related to the rear wheel steering of the vehicle, obtaining, by the processor, from the artificial neural network model, estimated data related to the rear wheel steering of the vehicle, as output data, obtaining, by the processor, from a sensor, measured data related to the rear wheel steering of the vehicle, comparing, by the processor, the estimated data and the measured data, and detecting, by the processor, the abnormality of the rear wheel steering motor based on a result of the comparison of the estimated data and the measured data.

According to still another aspect of the present disclosure, there is provided a non-transitory computer-readable storage medium in which a program including at least one instruction for performing the method of detecting an abnormality of a rear wheel steering motor is stored.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram schematically illustrating a configuration of a rear wheel steering system of a vehicle;

FIG. 2 is a diagram illustrating a detailed configuration and operation of a rear wheel steering motor controller of the rear wheel steering system;

FIG. 3 is a diagram illustrating a configuration of a device for detecting an abnormality of a rear wheel steering motor according to an embodiment of the present disclosure;

FIG. 4 is a diagram illustrating models, which are used to obtain an estimated value or detect an abnormality, in the device for detecting the abnormality of the rear wheel steering motor according to the embodiment of the present disclosure;

FIG. 5 is a diagram illustrating a detailed configuration of an artificial neural network model;

FIG. 6 is a diagram illustrating a detailed configuration of a generator of the artificial neural network model;

FIG. 7 is a diagram illustrating an operation of the device for detecting the abnormality of the rear wheel steering motor according to the embodiment of the present disclosure;

FIG. 8 is a flowchart of a method of detecting an abnormality of a rear wheel steering motor according to an embodiment of the present disclosure; and

FIG. 9 is a detailed flowchart of an operation of detecting the abnormality of the rear wheel steering motor in the method of detecting the abnormality of the rear wheel steering motor according to the embodiment of the present disclosure.

### DETAILED DESCRIPTION

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their disclosure.

In the specification, it should be understood that the terms “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

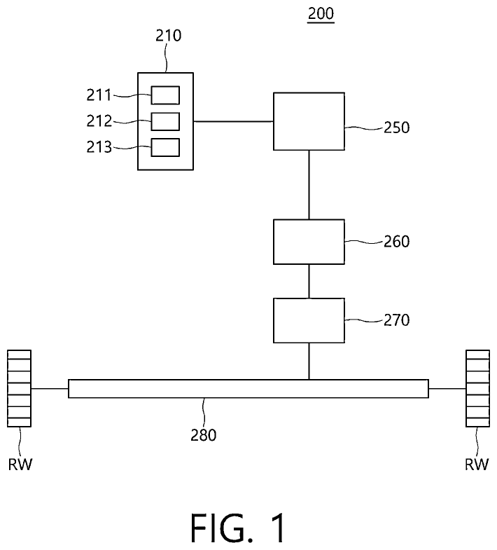

FIG. 1 is a diagram schematically illustrating a configuration of a rear wheel steering system of a vehicle.

A rear wheel steering system 200 actively controls a steering angle of rear wheels RW to match a steering angle of front wheels depending on a driving situation of a vehicle. Depending on the driving situation, the rear wheel steering system 200 may control the steering angle of the rear wheels RW in the same phase as the steering angle of the front wheels of the vehicle or in the opposite phase to the steering angle of the front wheels of the vehicle.

More specifically, when the vehicle is driven at medium or low speed, the rear wheels RW may be controlled in the opposite phase to the front wheels, thereby reducing a turning radius of the vehicle. Further, when the vehicle is driven at high speed, the rear wheels RW may be controlled in the same phase as the front wheels, thereby improving the stability of turning driving.

Referring to FIG. 1, the rear wheel steering system 200 includes a sensing unit 210 that detects information related to a driving state of the vehicle. The sensing unit 210 may include a vehicle speed sensor 211 that detects a speed of the vehicle, a shift lever position sensor 212 that detects shift lever position information of the vehicle, and a steering angle sensor 213 that detects a steering angle and steering angular velocity of a steering wheel of the vehicle.

The information detected by the sensing unit 210 may be transmitted to an electronic control unit 250. For example, information, such as the speed of the vehicle obtained from the vehicle speed sensor 211, the shift lever position information of the vehicle obtained through the shift lever position sensor 212, the steering angle and steering angular velocity of the steering wheel of the vehicle obtained from the steering angle sensor 213, etc., may be transmitted to the electronic control unit 250.

The electronic control unit 250 generates input data for rear wheel steering on the basis of the detected information. The input data generated by the electronic control unit 250 may be transmitted to a rear wheel steering motor controller 260, which controls a rear wheel steering motor 270 that generates a driving force for the rear wheel steering.

The rear wheel steering motor controller 260 controls the rear wheel steering motor 270 on the basis of the input data. The rear wheel steering motor 270 moves a rack 280 connected to the rear wheels RW of the vehicle. As the rack 280 is moved according to the driving of the rear wheel steering motor 270, the angle of the rear wheels RW of the vehicle may be changed and the rear wheel steering may be achieved.

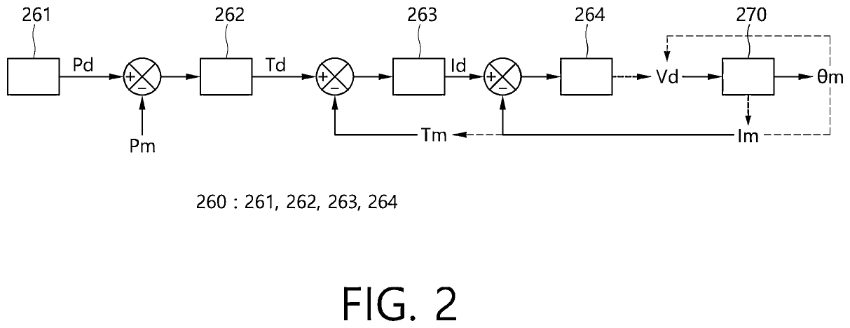

FIG. 2 is a diagram illustrating a detailed configuration and operation of the rear wheel steering motor controller of the rear wheel steering system.

Referring to FIG. 2, the rear wheel steering motor controller 260 may include a command generator 261, a rack position controller 262, a rear wheel steering motor torque controller 263, and a rear wheel steering motor current controller 264.

The command generator 261 generates a command for a rack position P_{d}, which is a rack position where the rack 280 should be located, according to the input data. In this case, the input data may include at least one of a speed of the vehicle, shift lever position information of the vehicle, a steering angle of the vehicle, and a steering angular velocity of the vehicle.

The rack position controller 262 receives a difference between the command for the rack position P_{d} and a measured rack position Pₘ and generates a command for a rear wheel steering motor torque T_{d}, which is a torque that should be generated by the rear wheel steering motor 270.

The difference between the command for the rack position P_{d} and the measured rack position Pₘ may be a difference between a command and a measurement value for the rack position and may be defined as a first residual. In other words, the rack position controller 262 may receive the first residual and generate the command for the rear wheel steering motor torque T_{d}.

The rear wheel steering motor torque controller 263 receives a difference between the command for the rear wheel steering motor torque T_{d} and a measured rear wheel steering motor torque Tₘ measured at the rear wheel steering motor 270 and generates a command for a current I_{d}, which is a current that should be supplied to the rear wheel steering motor 270.

The difference between the command for the rear wheel steering motor torque T_{d} and the measured rear wheel steering motor torque Tₘ may be a difference between a command and a measurement value for the motor torque and may be defined as a second residual. In other words, the rear wheel steering motor torque controller 263 may receive the second residual and generate the command for the current I_{d}.

The rear wheel steering motor current controller 264 receives an input current reflecting feedback of the command for the current I_{d} and a measured current Iₘ and controls a current supplied to the rear wheel steering motor 270. Accordingly, a voltage V_{d} input to the rear wheel steering motor 270 may be determined.

Meanwhile, the measured current Iₘ of the motor may be calculated from an angle θₘ (position) of the rear wheel steering motor 270. Further, the measured rear wheel steering motor torque Tₘ may be estimated from the measured current Iₘ of the rear wheel steering motor 270.

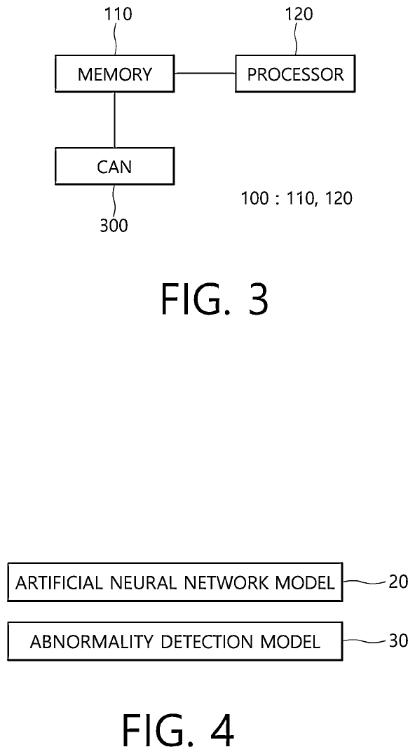

FIG. 3 is a diagram illustrating a configuration of a device for detecting an abnormality of a rear wheel steering motor according to an embodiment of the present disclosure. Further, FIG. 4 is a diagram illustrating models, which are used to obtain an estimated value or detect an abnormality, in the device for detecting the abnormality of the rear wheel steering motor according to the embodiment of the present disclosure.

A device 100 for detecting the abnormality of the rear wheel steering motor according to the embodiment of the present disclosure detects an abnormality of a rear wheel steering motor 270 that generates a driving force for driving a rack 280 that performs rear wheel steering of a vehicle. More specifically, the device 100 for detecting the abnormality of the rear wheel steering motor may detect a decrease in an output before the rear wheel steering motor 270 enters a failure state in which the rear wheel steering motor 270 is difficult to operate.

The device 100 for detecting the abnormality of the rear wheel steering motor according to the embodiment of the present disclosure may prognosticate degradation in function of the rear wheel steering motor 270 before a failure of the rear wheel steering motor 270 occurs using a digital twin algorithm based on artificial intelligence. The digital twin algorithm may virtually build a rear wheel steering system of the vehicle.

Referring to FIG. 3, the device 100 for detecting the abnormality of the rear wheel steering motor according to the embodiment of the present disclosure may include a memory 110 and a processor 120.

The memory 110 stores one or more instructions. The one or more instructions may be performed by the processor 120.

The memory 110 may include a hardware device configured to store the one or more instructions. For example, the memory 110 may include a storage medium such as a read-only memory (ROM), a random access memory (RAM), a flash memory, etc. Further, the memory 110 may include a magnetic medium such as a floppy disk or a magnetic tape, an optical medium such as a compact disc read only memory (CD-ROM) or a digital video disc (DVD), a magneto-optical medium such as a floptical disk, etc.

The processor 120 executes the one or more instructions. For example, the processor 120 may be a hardware unit that performs calculation and control in a computer. The processor 120 may include at least one arithmetic logic unit (ALU) and a register.

The processor 120 executes the one or more instructions to input input data related to steering of the vehicle into an artificial neural network model 20 and obtain estimated data related to rear wheel steering that is output by the artificial neural network model 20.

The input data may include at least one of a speed of the vehicle, shift lever position information of the vehicle, a steering angle of the vehicle, and a steering angular velocity of the vehicle. For example, the input data may include the speed of the vehicle, the shift lever position information of the vehicle, the steering angle of the vehicle, and the steering angular velocity of the vehicle.

The input data may be obtained from a controller area network (CAN) 300 of the vehicle. For example, the input data may be transmitted to the memory 110 through the CAN 300.

In this way, the input data may be obtained through the CAN 300 of the vehicle. Accordingly, according to the present disclosure, there is no need to use an additional sensor in relation to detecting the abnormality of the rear wheel steering motor 270.

In this regard, the memory 110 may be directly or indirectly connected to the CAN 300 of the vehicle. The memory 110 may receive the input data from the CAN 300. Accordingly, the processor 120 may obtain the input data from the memory 110.

The estimated data may include a first estimated value for a first residual, which is a difference between a command and a measurement value for a position of a rack that is determined to correspond to the input data. Further, the estimated data may further include a second estimated value for a second residual, which is a difference between a command and a measurement value for a motor torque to be generated by the rear wheel steering motor 270 that is determined to correspond to the input data.

The artificial neural network model 20 receives the input data and outputs the estimated data. More specifically, the artificial neural network model 20 may receive the input data and output the first estimated value and the second estimated value.

The estimated data is obtained to be compared with actual measurement data related to rear wheel steering. In this case, the actual measurement data may include a first actual measurement value, which is an actual measurement value of the first residual, and a second actual measurement value, which is an actual measurement value of the second residual.

In an embodiment of the present disclosure, the artificial neural network model 20 may consist of a generative adversarial network (GAN).

In an embodiment of the present disclosure, the artificial neural network model 20 may be a deep learning-based neural twin model for the rear wheel steering system of the vehicle. In other words, the artificial neural network model 20 may serve as a virtual twin model of the rear wheel steering system of the vehicle.

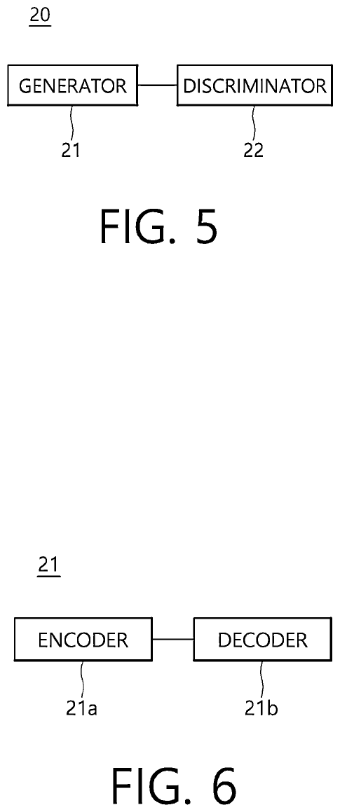

FIG. 5 is a diagram illustrating a detailed configuration of the artificial neural network model.

Referring to FIG. 5, the artificial neural network model 20 may include a generator 21 and a discriminator 22.

The artificial neural network model 20 may be constructed by alternately performing learning of the generator 21 and the discriminator 22, and data used when learning is performed may be obtained when the vehicle and the rear wheel steering system are in a normal state. Accordingly, the first estimated value and the second estimated value that are included in the estimated data may follow the first actual measurement value and the second actual measurement value that are obtained when the vehicle and the rear wheel steering system are in a normal state.

The generator 21 receives the input data and generates the estimated data. The generator 21 may include a neural network. The generator 21 may include a multivariate transformer. That is, the artificial neural network model 20 may be a GAN based on a multivariate transformer.

In an embodiment of the present disclosure, the generator 21 may receive input data related to rear wheel steering of the vehicle. As described above, the input data may include the speed of the vehicle, the steering angle of the steering wheel, and a propulsive force of the rack 280 that moves the wheels RW of the vehicle by receiving the driving force from the rear wheel steering motor 270.

The generator 21 may calculate the input data and output the estimated data. More specifically, the generator 21 may output the first estimated value for the first residual and the second estimated value for the second residual.

The estimated data output by the generator 21 follows the first actual measurement value of the first residual and the second actual measurement value of the second residual, which are output to correspond to the input data, when the rear wheel steering system of the vehicle is in a normal state.

FIG. 6 is a diagram illustrating a detailed configuration of the generator of the artificial neural network model.

Referring to FIG. 6, the generator 21 may include an encoder 21a and a decoder 21b.

The encoder 21a and the decoder 21b form a network for estimating the estimated data related to rear wheel steering of the vehicle. In other words, the generator 21 may include an encoder 21a-decoder 21b structured network trained in an end-to-end manner to estimate the estimated data.

The encoder 21a may be designed to extract high-level features from the input data using a transformer block and linear operation. In this case, the transformer block may include an embedding layer, a self-attention layer, and a feed-forward layer.

First, the embedding layer in the transformer block may encode spatiotemporal information into input sequences using a trainable embedding matrix.

Next, deep features may be extracted through the self-attention layer, and refinement may be performed using the feed-forward layer.

In this case, the self-attention layer may utilize a scaled dot-product attention mechanism. The self-attention layer may be a key component in transformer-based deep neural network (DNN) architectures, allowing the model to process and understand dependencies within the input sequence.

Scaled dot-product attention may first apply layer normalization to the input sequence and process results of the layer normalization into three unique vectors: a query (Q); a key (K); and a value (V) through linear operations.

Next, an attention score AS may be calculated for each position in the input sequence on the basis of the derived vectors. A calculation formula for the attention score AS may be given as Formula 1 below.

$$AS = σ ( \frac{Q \cdot K}{\sqrt{{‖ {x}_{input} ‖}_{dim}}} ) \cdot V \qquad ( Formula 1 )$$

(σ( ) denotes a softmax operation, |xᵢₙₚᵤₜ|_{dim} denotes a feature dimension of an input, and · denotes a dot product.)

An attention score quantifies the relative importance of each position in the input sequence relevant to a given query. That is, higher scores are assigned to more appropriate positions.

An output of the transformer block may be fed to two different linear operations to calculate a query, a key vector, and an initial input value ŷ1 of the decoder 21b.

The decoder 21b may estimate the estimated value using the obtained values in an auto-regressive manner similar to sequence-to-sequence recurrent neural networks.

Like the encoder 21a, the decoder 21b may include a transformer block and linear operations. Additionally, the decoder 21b may include a cross-attention layer within the transformer block.

The cross-attention layer may perform scaled dot-product attention using the query and key vector of the encoder 21a to learn a dynamic correlation between input signals and estimated signals.

The discriminator 22 receives the input data and the actual measurement data and outputs a discrimination value. The discrimination value output by the discriminator 22 for the input data and the actual measurement data may be defined as a discrimination value related to actual measurement.

The discriminator 22 is a classifier that aims to determine the conditional probability. The discriminator 22 determines the probability of an example being real or fake given that set of input features. The discrimination value from the discriminator 22 are classification labels. For example, the discrimination value from the discriminator 22 is 0 or 1.

Meanwhile, the discriminator 22 may additionally receive the input data and the estimated data and output a discrimination value. The discrimination value output by the discriminator 22 for the input data and the estimated data may be defined as a discrimination value related to estimation. Such a process may be accomplished when the generator 21 and the discriminator 22 perform learning.

In this way, the discriminator 22 outputs the discrimination value for the input data and the actual measurement data during an operation process for abnormality detection. Meanwhile, the discriminator 22 may output the discrimination value for the input data and the estimated data during an operation process for learning.

The discriminator 22 may include a discriminator network used for adversarial training of a GAN. In other words, the generator 21 and the discriminator 22 may be trained using an adversarial training method to improve estimation performance and establish a GAN model.

More specifically, the discriminator 22 may perform optimization alternately with the generator 21 to solve a Wasserstein min-max problem such as Formula 2.

$${min}_{G} {max}_{D} {E}_{{x}_{D , Real}} [ D ( {x}_{D , Real} ) ] - {E}_{{x}_{D , Fake}} [ D ( {x}_{D , Fake} ) ] \qquad ( Formula 2 )$$

(x_{D,Real} denotes a real data set consisting of the input data and the actual measurement data related to rear wheel steering, and x_{D,Fake} denotes a virtual data sample consisting of the input data and the estimated data related to rear wheel steering.)

In the artificial neural network model 20, the generator 21 is trained to deceive the Discriminator 22, which distinguishes the spatiotemporal characteristics of x_{D,Real} and x_{D,Fake}. Accordingly, the generator 21 may generate the estimated value for following the rear wheel steering system in a normal state.

In this regard, a loss function for GAN training may be defined as Formula 3 below.

$${L}_{G} = \frac{1}{N} \sum \vert {y}_{G} - {\hat{y}}_{G} \vert + 0.001 \times \frac{1}{N} \sum [ - D ( {x}_{D , Fake} ) ] , \qquad ( Formula 3 )$$

$${L}_{D} = \frac{1}{N} \sum [ D ( {x}_{D , Fake} ) - D ( {x}_{D , Real} ) ] + 10 \times \frac{1}{N} \sum [ {( {‖ {∇}_{{x}_{D , Fake}} D ( {x}_{D , Fake} ) ‖}_{2} - 1 )}^{2} ]$$

(N denotes a size of a batch, LG denotes a loss function of the generator, and LD denotes a loss function of the discriminator.)

The first term of the loss function of the generator 21 corresponds to a loss L_{MAE} of a mean absolute error of supervised training. The remaining term of the loss function of the generator 21 together with a loss function of the discriminator 22 constitute a loss function L_{GAN} of the GAN.

Further, the processor 120 compares the estimated data with the actual measurement data and detects the abnormality of the rear wheel steering motor 270. As described above, the estimated data may include the first estimated value for the first residual and the second estimated value for the second residual. Further, the actual measurement data may include the first actual measurement value, which is the actual measurement value of the first residual, and the second actual measurement value, which is the actual measurement value of the second residual.

The processor 120 may execute the one or more instructions to input error data related to the difference between the estimated data and the actual measurement data into an abnormality detection model 30 and determine whether the rear wheel steering motor is abnormal. For example, the abnormality detection model 30 may use a one-class support vector machine (OCSVM) algorithm.

There may be a plurality of data sets including the input data, the estimated data, and the actual measurement data. The error data may include a mean and standard deviation of errors between the actual measurement data and the estimated data of the plurality of data sets, a maximum absolute error between the actual measurement data and the estimated data of the plurality of data sets, and a discrimination value of the discriminator 22 related to actual measurement for the input data and the actual measurement data included in the plurality of data sets.

In an embodiment of the present disclosure, the error data may include a mean of errors between the first estimated value and the first actual measurement value, a standard deviation between the first estimated value and the first actual measurement value, a maximum absolute error between the first estimated value and the first actual measurement value, a mean of errors between the second estimated value and the second actual measurement value, a standard deviation between the second estimated value and the second actual measurement value, a maximum absolute error between the second estimated value and the second actual measurement value, and a discrimination value of the discriminator for the input data, the first actual measurement value, and the second actual measurement value.

The plurality of data sets including the input data, the estimated data, and the actual measurement data may be treated as one batch. For example, 100 to 150 data sets (as a specific example, 128 data sets) may be treated as one batch, and the error data may be obtained for each batch.

The error data obtained for one batch may be input into the abnormality detection model 30. Further, the level of the abnormality of the rear wheel steering motor (degradation in performance of the rear wheel steering motor) may be detected based on an output (characteristic) obtained from the abnormality detection model 30 that receives the error data.

Regarding an anomaly detection metric, an F1 score given as Formula 4 below may be considered.

$$F 1 = \frac{2 \times TP}{2 \times TP + FP + FN} \qquad ( Formula 4 )$$

(TP denotes true positive, FP denotes false positive, and FN denotes false negative, wherein positive indicates degradation in performance of the rear wheel steering motor.)

Meanwhile, as described above, the discriminator 22 may calculate not only the discrimination value for the input data and the actual measurement data included in the data set, but also the discrimination value for the input data and the estimated data included in the data set. The discrimination value of the discriminator 22 for the estimated data of the data set may be provided as feedback to the generator 21 of the artificial neural network model 20 and used for training.

Until now, the configuration of the device 100 for detecting the abnormality of the rear wheel steering motor according to the embodiment of the present disclosure has been described in detail. Hereinafter, the operation of the device 100 for detecting the abnormality of the rear wheel steering motor will be described in detail.

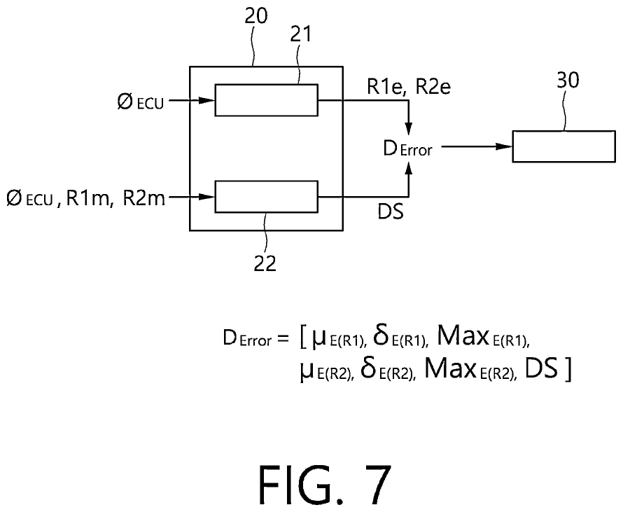

FIG. 7 is a diagram illustrating an operation of the device for detecting the abnormality of the rear wheel steering motor according to the embodiment of the present disclosure.

Referring to FIG. 7, the device 100 for detecting the abnormality of the rear wheel steering motor according to the embodiment of the present disclosure may operate as follows.

First, the memory 110 stores input data Ø_{ECU} and actual measurement data. In this case, the actual measurement data may include a first actual measurement value R1ₘ obtained by actually measuring a first residual and a second actual measurement value R2ₘ obtained by actually measuring a second residual.

As described above, the input data Ø_{ECU} may include at least one of a speed of the vehicle, shift lever position information of the vehicle, a steering angle of the vehicle, and a steering angular velocity of the vehicle. Further, a plurality of pieces of actual measurement data including the input data ØECU, the first actual measurement value R1ₘ, and the second actual measurement value R2ₘ may be treated as one batch. That is, in an embodiment of the present disclosure, data processing and calculations may be performed in units of data batches.

Next, the processor 120 executes the one or more instructions to input the input data ØECU into the artificial neural network model 20 and obtain the estimated data output by the artificial neural network model 20. More specifically, the processor 120 may input the input data ØECU into the generator 21 of the artificial neural network model 20 and obtain the estimated value including a first estimated value R1ₑ, which is an estimated value of the first residual output by the generator 21, and a second estimated value R2ₑ, which is estimated data of the second residual.

Further, the processor 120 executes the one or more instructions to input the input data Ø_{ECU}, the first actual measurement value R1ₘ, and the second actual measurement value R2ₘ into the artificial neural network model 20 and obtain a discrimination value DS. More specifically, the processor 120 may input the input data Ø_{ECU}, the first actual measurement value Rlm, and the second actual measurement value R2ₘ into the discriminator 22 and obtain the discrimination value DS.

Next, the processor 120 outputs error data D_{Error}. The error data D_{Error} may be output for each data batch.

More specifically, there are the plurality of data sets including the input value, the one or more estimated values, and the one or more actual measurement values.

In this case, the error data D_{Error} may include a mean μ_{E(R1)} of errors between the first estimated value R1ₑ and the first actual measurement value R1ₘ, a standard deviation σ_{E(R1)} between the first estimated value R1ₑ and the first actual measurement value R1ₘ, a maximum absolute error Max_{E(R1)} between the first estimated value R1ₑ and the first actual measurement value R1ₘ, a mean μ_{E(R2)} of errors between the second estimated value R2ₑ and the second actual measurement value R2ₘ, a standard deviation σ_{E(R2)} between the second estimated value R2, and the second actual measurement value R2ₘ, a maximum absolute error Max_{E(R2)} between the second estimated value R2ₑ and the second actual measurement value R2ₘ, and a discrimination value DS of the discriminator for the input data Ø_{ECU}, the first actual measurement value R1ₘ, and the second actual measurement value R2ₘ.

Lastly, the processor 120 executes the one or more instructions to input the error data D_{Error} into the abnormality detection model 30 and obtain an output of the abnormality detection model 30. As described above, the abnormality detection model 30 may include an OCSVM algorithm.

Based on the output (characteristic) obtained from the abnormality detection model 30 that receives the error data D_{Error}, the processor 120 may detect the level of the abnormality (degradation in performance of the rear wheel steering motor) of the rear wheel steering motor of the rear wheel steering system.

As described above, the device 100 for detecting the abnormality of the rear wheel steering motor according to the embodiment of the present disclosure has been described in detail. Hereinafter, a method of detecting an abnormality of a rear wheel steering motor will be described.

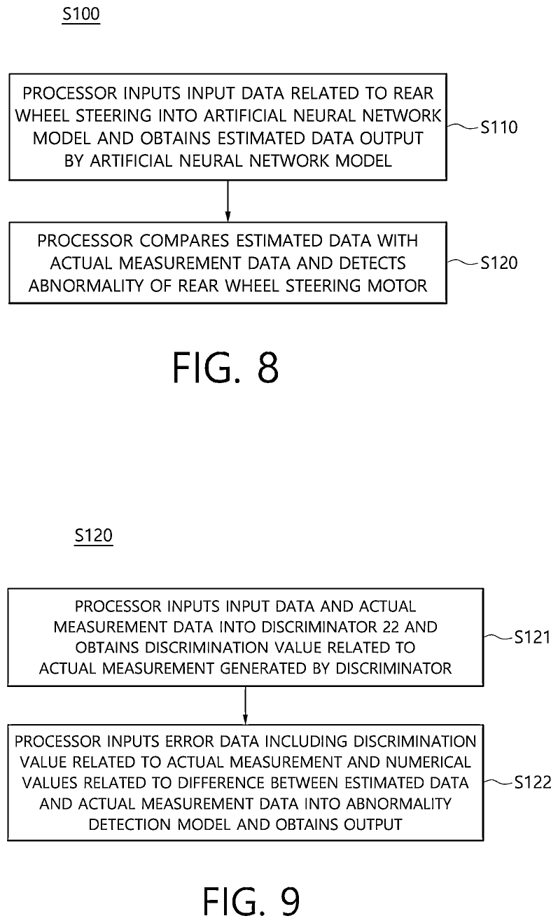

FIG. 8 is a flowchart of a method of detecting an abnormality of a rear wheel steering motor according to an embodiment of the present disclosure.

In a method S100 of detecting the abnormality of the rear wheel steering motor according to the embodiment of the present disclosure, the abnormality of the rear wheel steering motor that generates a driving force for driving a rack that performs rear wheel steering of a vehicle is detected.

Referring to FIG. 8, the method S100 of detecting the abnormality of the rear wheel steering motor according to the embodiment of the present disclosure may be performed as follows.

First, the processor 120 inputs input data related to the rear wheel steering of the vehicle into the artificial neural network model 20 and obtains estimated data related to rear wheel steering that is output by the artificial neural network model 20 (S110).

The input data may include at least one of a speed of the vehicle, shift lever position information of the vehicle, a steering angle of the vehicle, and a steering angular velocity of the vehicle. In an embodiment of the present disclosure, the input data may include the speed of the vehicle, the shift lever position information of the vehicle, the steering angle of the vehicle, and the steering angular velocity of the vehicle.

Meanwhile, the input data may be obtained from the CAN 300 of the vehicle.

The estimated data may include a first estimated value for a first residual, which is a difference between a command and a measurement value for a position of the rack 280 that is determined to correspond to the input data. Further, the estimated data may further include a second estimated value for a second residual, which is a difference between a command and a measurement value for a motor torque transmitted to the rear wheel steering motor 270 that is determined to correspond to the input data.

The estimated data is obtained to be compared with actual measurement data related to steering. In this case, the actual measurement data may include a first actual measurement value which is an actual measurement value of the first residual, and a second actual measurement value, which is an actual measurement value of the second residual.

In an embodiment of the present disclosure, the artificial neural network model 20 may include a GAN. In other words, the artificial neural network model 20 may be a deep learning-based neural twin model for the rear wheel steering system of the vehicle.

The artificial neural network model 20 may include a generator 21 and a discriminator 22. The generator 21 receives the input data and generates the estimated data. The generator 21 may include a multivariate transformer. Further, the discriminator 22 may receive the input data and the actual measurement data and output a discrimination value related to actual measurement.

In operation S110 of obtaining the estimated data, the processor 120 may input the input data into the generator 21 and obtain the estimated value generated by the generator 21.

Meanwhile, the artificial neural network model 20 is constructed by the generator 21 and the discriminator 22 performing learning, and the input data and the actual measurement data that are used during the learning may be obtained when the vehicle and the rear wheel steering system are in a normal state. Accordingly, the estimated data may follow the actual measurement data related to rear wheel steering that is obtained when the rear wheel steering system is in a normal state.

Next, the processor 120 compares the estimated data with the actual measurement data and detects the abnormality of the rear wheel steering motor (S120).

The processor 120 may execute the one or more instructions to input error data related to a difference between the estimated data and the actual measurement data into the abnormality detection model 30 and determine whether the rear wheel steering motor is abnormal. For example, the abnormality detection model 30 may use an OCSVM algorithm.

FIG. 9 is a detailed flowchart of an operation of detecting the abnormality of the rear wheel steering motor in the method of detecting the abnormality of the rear wheel steering motor according to the embodiment of the present disclosure.

Referring to FIG. 9, the operation S120 of detecting the abnormality of the rear wheel steering motor may be performed as follows.

First, the processor 120 inputs the input data and the actual measurement data into the discriminator 22 and obtains a discrimination value related to actual measurement generated by the discriminator 22 (S121).

Next, the processor 120 inputs error data including the discrimination value related to actual measurement and numerical values related to the difference between the estimated data and the actual measurement data into the abnormality detection model 30 and obtains an output of the abnormality detection model 30 (S122).

There may be a plurality of data sets including the input data, the estimated data, and the actual measurement data. The error data may include a mean and standard deviation of errors between the actual measurement data and the estimated data of the plurality of data sets, a maximum absolute error between the actual measurement data and the estimated data of the plurality of data sets, and the discrimination value of the discriminator 22 for the input data and the actual measurement data included in the plurality of data sets.

In an embodiment of the present disclosure, the error data may include a mean of errors between the first estimated value and the first actual measurement value, a standard deviation between the first estimated value and the first actual measurement value, a maximum absolute error between the first estimated value and the first actual measurement value, a mean of errors between the second estimated value and the second actual measurement value, a standard deviation between the second estimated value and the second actual measurement value, a maximum absolute error between the second estimated value and the second actual measurement value, and a discrimination value of the discriminator for the input data, the first actual measurement value, and the second actual measurement value.

The plurality of data sets including the estimated data and the actual measurement data may be treated as one batch. For example, 100 to 150 data sets (as a specific example, 128 data sets) may be treated as one batch, and the error data may be obtained for each batch.

The error data obtained for one batch may be input into the abnormality detection model 30. Further, the level of the abnormality of the rear wheel steering motor (degradation in performance of the rear wheel steering motor) may be detected based on an output (characteristic) obtained from the abnormality detection model 30 that receives the error data.

Meanwhile, the present disclosure additionally provides a non-transitory computer-readable storage medium storing a program for performing the method of detecting an abnormality of a rear wheel steering motor. Specifically, the present disclosure may provide a non-transitory computer-readable storage medium in which a program including at least one instruction for performing the method of detecting an abnormality of a rear wheel steering motor is stored.

In this case, the instruction may include not only machine code generated by a compiler but also high-level language code executable by a computer.

The non-transitory computer-readable storage medium may include a magnetic medium such as a hard disk, a floppy disk, and a magnetic tape, an optical medium such as a CD-ROM and a DVD, a magneto-optical medium such as a floptical disk, and a hardware device configured to store and execute program instructions, such as a ROM, a RAM, a flash memory, etc.

Regarding an anomaly detection metric, an F1 score given as described above may be considered.

As a result of a simulation, it was found that according to the present disclosure, a decrease up to 10% of a maximum output of the rear wheel steering motor can be predicted with the performance of an F1 score of 0.85 or higher. In other words, according to the present disclosure, the level of degradation of the rear wheel steering motor can be accurately predicted before the rear wheel steering motor, which is disposed in the rear wheel steering system and generates the driving force for driving the steering of rear wheels, completely fails.

According to the present disclosure, it is possible to predict an abnormality of the rear wheel steering motor of the rear wheel steering system before the rear wheel steering motor of the rear wheel steering system completely fails. As a result, it is possible to take proactive measures before a failure of the rear wheel steering motor occurs, and to prevent the failure of the rear wheel steering motor.

In this way, the present disclosure provides the estimation of the future operation and remaining useful life of the system and the prognostic diagnosis suitable for predictive maintenance applications. Accordingly, proactive measures and maintenance can be effectively guided before a failure of the rear wheel steering motor of the rear wheel steering system occurs.

According to the above configuration, in the device and method for detecting the abnormality of the rear wheel steering motor, and the non-transitory computer-readable storage medium storing the program for performing the method according to an aspect of the present disclosure, it is possible to prognosticate degradation in performance of the rear wheel steering motor before a failure of the rear wheel steering motor that generates the driving force for driving the rack that performs rear wheel steering of the vehicle occurs based on an artificial intelligence-based digital twin algorithm.

Further, in the device and method for detecting the abnormality of the rear wheel steering motor, and the non-transitory computer-readable storage medium storing the program for performing the method according to an aspect of the present disclosure, it is possible to predict degradation in performance of the rear wheel steering motor using signals of a CAN of the vehicle without a separate additional sensor.

It should be understood that the effects of the present disclosure are not limited to the above-described effects, and include all effects inferable from a configuration of the invention described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A device, comprising:
a memory configured to store one or more instructions; and
a processor configured to detect an abnormality of a rear wheel steering motor that generates a driving force for driving a rack that performs rear wheel steering of a vehicle, by executing the one or more instructions stored in the memory,
wherein the processor is configured to:
input, into an artificial neural network model, input data related to the rear wheel steering of the vehicle;
obtain, from the artificial neural network model, estimated data related to the rear wheel steering of the vehicle, as output data;
obtain, from a sensor, measured data related to the rear wheel steering of the vehicle;
compare the estimated data and the measured data; and
detect the abnormality of the rear wheel steering motor based on a result of the comparison of the estimated data and the measured data.

2. The device of claim 1, wherein the input data comprise information on at least one of a speed of the vehicle, a shift lever position of the vehicle, a steering angle of the vehicle, and a steering angular velocity of the vehicle.

3. The device of claim 2, wherein the estimated data comprise a first estimated value for a first residual, which is a difference between a command and a measurement value for a position of the rack that is determined to correspond to the input data, and
wherein the measured data comprise a first actual measurement value, which is an actual measurement value of the first residual.

4. The device of claim 3, wherein the estimated data further comprise a second estimated value for a second residual, which is a difference between a command and a measurement value for a motor torque to be generated by the rear wheel steering motor that is determined to correspond to the input data, and
wherein the measured data further comprise a second actual measurement value, which is an actual measurement value of the second residual.

5. The device of claim 1, wherein the processor is further configured to obtain the input data through a controller area network (CAN) of the vehicle.

6. The device of claim 1, wherein the artificial neural network model comprises a generative adversarial network (GAN) including a generator configured to receive the input data and generate the estimated data, and a discriminator configured to receive the input data and the measured data, and output a discrimination value related to actual measurement.

7. The device of claim 6, wherein the generator includes a multivariate transformer.

8. The device of claim 6, wherein the processor is further configured to input error data related to a difference between the estimated data and the measured data into an abnormality detection model to detect the abnormality of the rear wheel steering motor.

9. The device of claim 8, wherein the abnormality detection model uses a one-class support vector machine (OCSVM) algorithm.

10. The device of claim 8, wherein:
the estimated data comprise a plurality of estimated values;
the measured data comprise a plurality of measured values;
the input data comprise a plurality of input values; and
the error data comprise a mean and standard deviation of errors between the plurality of estimated values and the plurality of measured values, a maximum absolute error among the errors, and the discrimination value of the discriminator for the plurality of input values and the plurality of measured values.

11. The device of claim 6, wherein the discriminator is further configured to additionally receive the input data and the estimated data, and additionally output an additional discrimination value related to estimation.

12. The device of claim 11, wherein the artificial neural network model is constructed by alternately performing learning of the generator and the discriminator, and
wherein the input data and the measured data are obtained when the vehicle and the rear wheel steering motor are in a normal state, and inputted into the artificial neural network model for performing learning of the generator and the discriminator.

13. A method of detecting an abnormality of a rear wheel steering motor of a vehicle, performed by a processor, the method comprising:
inputting, by the processor, into an artificial neural network model, input data related to the rear wheel steering of the vehicle;
obtaining, by the processor, from the artificial neural network model, estimated data related to the rear wheel steering of the vehicle, as output data;
obtaining, by the processor, from a sensor, measured data related to the rear wheel steering of the vehicle;
comparing, by the processor, the estimated data and the measured data; and
detecting, by the processor, the abnormality of the rear wheel steering motor based on a result of the comparison of the estimated data and the measured data.

14. The method of claim 13, wherein the input data comprise information on at least one of a speed of the vehicle, a shift lever position of the vehicle, a steering angle of the vehicle, and a steering angular velocity of the vehicle.

15. The method of claim 14, wherein the estimated data comprise a first estimated value for a first residual, which is a difference between a command and a measurement value for a position of a rack that performs rear wheel steering of a vehicle, wherein the position is determined to correspond to the input data, and
wherein the measured data comprise a first actual measurement value, which is an actual measurement value of the first residual.

16. The method of claim 15, wherein the estimated data further comprise a second estimated value for a second residual, which is a difference between a command and a measurement value for a motor torque to be generated by the rear wheel steering motor that is determined to correspond to the input data, and
wherein the measured data further comprise a second actual measurement value, which is an actual measurement value of the second residual.

17. The method of claim 13, wherein the artificial neural network model comprises a generative adversarial network (GAN) including:
a generator configured to receive the input data and generate the estimated data, and
a discriminator configured to receive the input data and the measured data, and output a discrimination value related to actual measurement.

18. The method of claim 17, wherein the detecting comprises:
inputting, by the processor, the input data and the measured data into the discriminator, and obtaining by the processor, the discrimination value related to actual measurement generated by the discriminator; and
inputting, by the processor, error data including the discrimination value and a value related to a difference between the estimated data and the measured data into an abnormality detection model, and obtaining, by the processor, an output of the abnormality detection model.

19. The method of claim 18, wherein:
the estimated data comprise a plurality of estimated values;
the measured data comprise a plurality of measured values;
the input data comprise a plurality of input values; and
the error data comprise a mean and standard deviation of errors between the plurality of estimated values and the plurality of measured values, a maximum absolute error among the errors, and the discrimination value of the discriminator for the plurality of input values and the plurality of measured values.

20. A non-transitory computer-readable storage medium configured to store at least one instruction, that when executed by a processor, causes the processor to perform operations of detecting an abnormality of a rear wheel steering motor configured to generate a driving force for driving a rack that performs rear wheel steering of a vehicle, the operations comprising:
inputting, by the processor, into an artificial neural network model, input data related to the rear wheel steering of the vehicle;
obtaining, by the processor, from the artificial neural network model, estimated data related to the rear wheel steering of the vehicle, as output data;
obtaining, by the processor, from a sensor, measured data related to the rear wheel steering of the vehicle;
comparing, by the processor, the estimated data and the measured data; and
detecting, by the processor, the abnormality of the rear wheel steering motor based on a result of the comparison of the estimated data and the measured data.
